(19) United States
(12) Patent Application Publication
(10) Pub. No.: US 2025/0013813 A1
(43) Pub. Date: Jan. 9, 2025

(54) ACTION MASKS FOR MACRO PLACEMENT BASED ON DENSITY MAP CALCULATIONS

(71) Applicant: MediaTek Inc., Hsinchu City (TW)

(72) Inventors: Da-Shan SHIU, Hsinchu City (TW); Alexandru CIOBA, Cambridge (GB); Fu-Chieh CHANG, Hsinchu City (TW)

(21) Appl. No.: 18/264,303

(22) PCT Filed: Mar. 17, 2023
(86) PCT No.: PCT/CN2023/082288

§ 371 Date: Aug. 4, 2023

Related U.S. Application Data
(60) Provisional application No. 63/323,544, filed on Mar. 25, 2022.

(51) Int. Cl. G06F 30/392; G06F 30/398

(52) U.S. Cl. CPC G06F 30/392; G06F 30/398

(57) ABSTRACT

Macros are placed on a canvas based on density map calculations. First, a grid representing the canvas is initialized. The grid is formed by grid cells. To place a macro on the grid, a coordinate on the grid is chosen, and multiple density maps are calculated using average-pooling filters of multiple resolutions or orientations. The lowest-level density map is described by the grid with each grid cell having a corresponding density value. The density value in a higher-level density map is calculated by performing an average-pooling operation on density values in a lower- level density map. The placement of the macro at the coordinate is validated when no density value in the density maps exceeds a corresponding density threshold.

### CROSS-REFERENCE TO RELATED APPLICATIONS

This application claims the benefit of U.S. Provisional Application No. 63/323,544 filed on Mar. 25, 2022, the entirety of which is incorporated by reference herein.

### TECHNICAL FIELD

Embodiments of the invention relate to methods and apparatuses based on macro density for generating a macro placement on a semiconductor chip.

### BACKGROUND

In an integrated circuits (IC) design, a macro is a set of circuit components that can be viewed as a black box. The logic and electronic behavior of the macro are given but the internal structural description may or may not be known. Mixed-size macro placement is the problem of placing macros of various sizes on a chip canvas to optimize an objective such as wirelength, congestion, etc.

The process of macro placement typically starts with a grid discretization step, during which the placement area, also referred to as a canvas, is partitioned into equal-sized grid cells. During the macro placement, the center of each macro is aligned with the center of one of the grid cells. A placement tool can be programmed to place the macros on the grid. A placement tool that places macros compactly may generate a placement with a large amount of overlap among the macros, which increases the difficulties for further refining the macros' positions. When there is a large amount of overlap among the macros, a refinement process may push some macros far away from their original positions, resulting in the degradation of placement quality. On the other hand, a placement tool that places macros less compactly may generate a placement with a large amount of empty space that cannot be utilized for the placement of macros or standard cells. As such, there is a need for improving the existing techniques for macro placement.

### SUMMARY

In one embodiment, a method is provided for macro placement on a canvas represented by a grid of grid cells. The method comprises initializing the grid; choosing a coordinate on the grid to place a macro; and calculating density maps using average-pooling filters of multiple resolutions or orientations. The lowest-level density map is described by the grid with each grid cell having a corresponding density value. The density value in a higher-level density map is calculated by performing an average-pooling operation on density values in a lower-level density map. The method further comprises validating the placement of the macro at the coordinate when no density value in the density maps exceeds a corresponding density threshold.

In another embodiment, a system is operative to perform macro placement on a canvas represented by a grid of grid cells. The system comprises processing hardware and memory coupled to the processing hardware. The processing hardware is operative to initialize the grid; choose a coordinate on the grid to place a macro; and calculate density maps using average-pooling filters of multiple resolutions or orientations. The lowest-level density map is described by the grid with each grid cell having a corresponding density value. The density value in a higher-level density map is calculated by performing an average-pooling operation on density values in a lower- level density map. The processing hardware is further operative to validate the placement of the macro at the coordinate when no density value in the density maps exceeds a corresponding density threshold.

Other aspects and features will become apparent to those ordinarily skilled in the art upon review of the following description of specific embodiments in conjunction with the accompanying figures.

### BRIEF DESCRIPTION OF THE DRAWINGS

The present invention is illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one. Further, when a particular feature, structure, or characteristic is described in connection with an embodiment, it is submitted that it is within the knowledge of one skilled in the art to effect such feature, structure, or characteristic in connection with other embodiments whether or not explicitly described.

FIG. 1 illustrates examples of density maps and average-pooling filters of a multi-resolution action mask according to one embodiment.

FIG. 2 illustrates a grid and a padded grid overlaying a canvas according to one embodiment.

FIG. 3 illustrates an example of density map initialization according to one embodiment.

FIG. 4 illustrates the generation of higher-level density maps according to one embodiment.

FIG. 5 illustrates an example of placing a macro M1 onto a canvas according to one embodiment.

FIG. 6 illustrates an example of placing a second macro M2 according to one embodiment.

FIG. 7 illustrates another example of placing macro M2 according to one embodiment.

FIG. 8 is a flow diagram illustrating a method for macro placement according to a first embodiment.

FIG. 9 illustrates an example of a vertical average-pooling filter of a 1-D action mask according to one embodiment.

FIG. 10 illustrates an example of a horizontal average-pooling filter of a 1-D action mask according to one embodiment.

FIG. 11 illustrates an example of placing a macro M3 onto a canvas according to one embodiment.

FIG. 12 illustrates an example of placing a second macro M4 according to one embodiment.

FIG. 13 illustrates another example of placing macro M4 according to one embodiment.

FIG. 14 is a flow diagram illustrating a method for macro placement according to a second embodiment.

FIG. 15 is a flow diagram illustrating a method for macro placement according to an alternative embodiment that combines the first and the second embodiments.

FIG. 16 is a flow diagram illustrating a method for macro placement according to one embodiment.

FIG. 17 illustrates an example of a system according to one embodiment.

### DETAILED DESCRIPTION

In the following description, numerous specific details are set forth. However, it is understood that embodiments of the invention may be practiced without these specific details. In other instances, well-known circuits, structures, and techniques have not been shown in detail in order not to obscure the understanding of this description. It will be appreciated, however, by one skilled in the art, that the invention may be practiced without such specific details. Those of ordinary skill in the art, with the included descriptions, will be able to implement appropriate functionality without undue experimentation.

The disclosure herein provides systems and methods for macro placement based on density map calculations. The placement area (also referred to as a canvas) is discretized into a grid of equal-sized squares, where each square is referred to as a grid cell and has a size of (1 unit length×1 unit length). The macro density within a grid cell, also referred to as a density value, is defined as the sum of areas occupied by all of the macros within the grid cell divided by the grid cell's area. Each grid cell's area may be 1 by definition. A density map is a grid with each grid cell having a density value. A density threshold is used to control the maximum density value in a density map. Setting a higher density threshold allows macros to be placed more compactly, but may induce more overlapping among the macros and increase the difficulties for further refinement on the macros' positions. Setting a lower density threshold can alleviate the macros overlapping problem, but may induce more empty space among the macros and reduce the utilization of canvas space. The following two embodiments of action masks are proposed to improve macro placement.

In a first embodiment, a multi-resolution action mask and its corresponding density thresholds are defined over multiple combinations of grid cells on a canvas. A multi-resolution action mask is calculated using several levels of density maps and two-dimensional (2-D) average-pooling filters. The multi-resolution action mask not only allow macros to be placed compactly but also reserve enough space among the macros for further refinement.

In a second embodiment, a one-dimensional (1-D)) action mask is calculated using two 1-D average-pooling filters in both the horizontal and vertical directions. One common scenario of overlapping macros is that the macros are overlapped within a vertical or a horizontal canvas strip. The 1-D action mask is used to control the density of 1-D strips. The 1-D action masks are a variant of multi-resolution action masks.

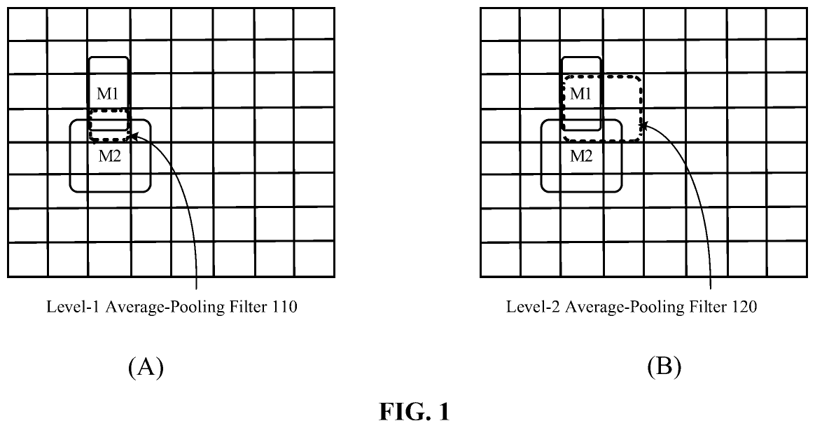

FIG. 1 illustrates an example of a multi-resolution action mask according to one embodiment. A macro placement tool is to determine whether it is allowed to place a first macro (M1) and a second macro (M2) on a grid representing a canvas as shown. In (A), the macro placement tool places a 1×1 average-pooling filter (i.e., 1 unit length×1 unit length in size) over a grid cell where a first macro (M1) and a second macro (M2) overlap. The 1×1 average-pooling filter is called a level-1 average-pooling filter 110. The macro density in the grid cell within average-pooling filter 110 is compared with a predetermined density threshold (e.g., 1.5). If the macro density is greater than the density threshold, the placement is not allowed. If the macro density is not greater than the density threshold, the placement tool proceeds to (B), in which a 2×2 average-pooling filter is placed over four grid cells. The 2×2 average-pooling filter is called a level-2 average-pooling filter 120. The macro density in the grid cells within average-pooling filter 120 is compared with a predetermined density threshold (e.g., 1). If the macro density is greater than the density threshold, the placement is not allowed. If the macro density is not greater than the density threshold, the placement tool may proceed to place a higher-level average-pooling filter (e.g., 4×4, 8×8, etc.) over the grid to determine whether the placement is allowed.

A placement tool applies an average-pooling filter on a grid with a stride size equal to a dimension size of the average-pooling filter. For example, the stride size of a 2×2 average-pooling filter is equal to 2. The average-pooling filter is applied to all of the grid cells to produce a density map. In some embodiments, instead of using increasingly larger average-pooling filters on the same grid to produce increasingly higher levels of density maps, a placement tool may use an average-pooling filter of the same size on increasingly smaller grids to produce increasingly higher levels of density maps.

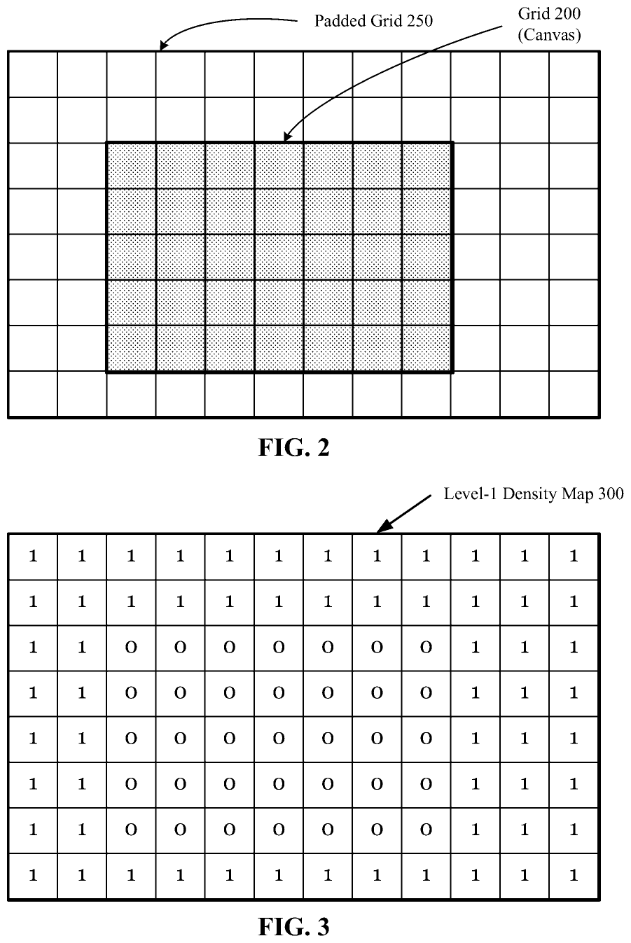

FIG. 2 illustrates a grid 200 and a padded grid 250 overlaying a canvas according to one embodiment. In FIG. 2, a canvas is overlaid with grid 200 of height=5 cells and width=7 cells (i.e., H=5, W=7). In the following description, grid 200 represents the canvas on which macros are to be placed. Grid 200 is padded with column(s) and or row(s) of grid cells to form padded grid 250, such that the overall grid width and height are divisible by 2^{(L-1)}, where L is the number of levels of density maps to be generated. The padded column(s) and row(s) are placed at the outer perimeter of grid 200. In one embodiment, grid 200 is placed at or near the center of padded grid 250. That is, the difference in the numbers of padded columns at the left and the right of grid 200 is either zero or one, and the difference in the numbers of padded rows at the top and the bottom of grid 200 is also either zero or one.

FIG. 3 illustrates an example of density map initialization according to one embodiment. FIG. 3 shows a level-1 density map 300 initialized on padded grid 250 (FIG. 2), where density=1 is assigned to the padded grid cells and density=0 is assigned to the cells of unpadded grid cells (i.e., the cells of grid 200).

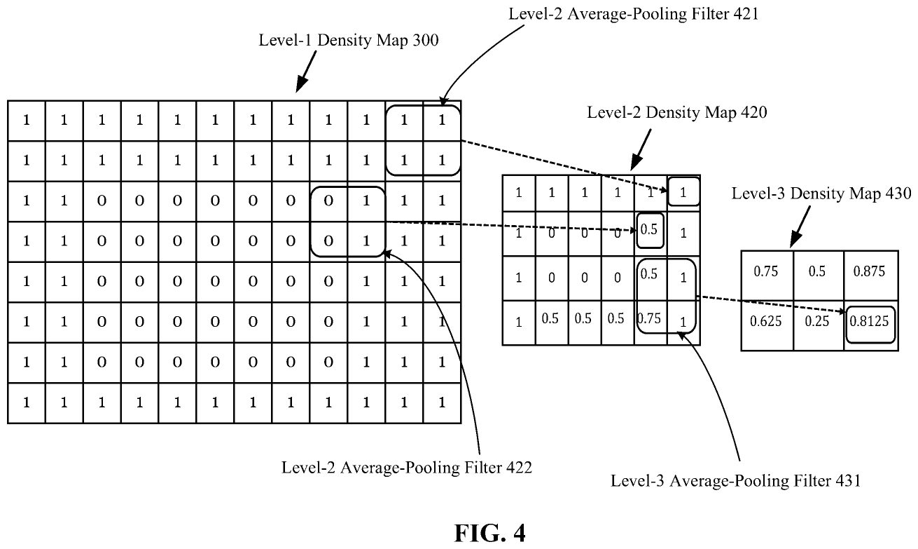

FIG. 4 illustrates the generation of higher-level density maps according to one embodiment. A level-2 density map 420 is calculated from level-density map 300. Each density value in level-2 density map 420 is the average density values of (2×2) cells in level-1 density map 300. For example, a (2×2) level-2 average-pooling filter 421 is applied to four cells of density=1, 1, 1, 1 in level-1 density map 300 to generate density=1 in the corresponding cell of level-2 density map 420. Another (2×2) level-2 average-pooling filter 422 is applied to four cells of density=0, 0, 1, 1 in level-1 density map 300 to generate density=(0+0+1+1)/4=0.5 in the corresponding cell of level-2 density map 420. As level-1 density map 300 has H=8 and W=12, level-2 density map 420 has H=( 8/2)=4 and W=( 12/2)=6.

Similarly, a level-3 density map 430 is calculated from level-2 density map 420. Each density value of level-3 density map 430 is the average density values of (2×2) cells in level-2 density map 420. For example, a (2×2) level-3 average-pooling filter 431 is applied to four cells of density=0.5, 0.75, 1, 1 in level-2 density map 420 to generate density=(0.5+0.75+1+1)/4=0.8125 in the corresponding cell of level-3 density map 430. As level-2 density map 420 has H=4 and W=6, level-3 density map 430 has H=( 4/2)=2 and W=( 6/2)=3.

It is noted that a (2×2) average-pooling filter applied to a level-2 density map is equivalent to a (4×4) average-pooling filter applied to a level-1 density map. Thus, although the level-2 and level-3 average-pooling filters in FIG. 2 have the same size of (2×2), these average-pooling filters correspond to different resolutions as they are applied to different levels of density maps.

The process of density map calculation is performed when each macro is placed on a selected coordinate of the padded grid. The density value at each level is compared with a corresponding density threshold. If at any level a density value exceeds the corresponding density threshold, the macro placement is disallowed.

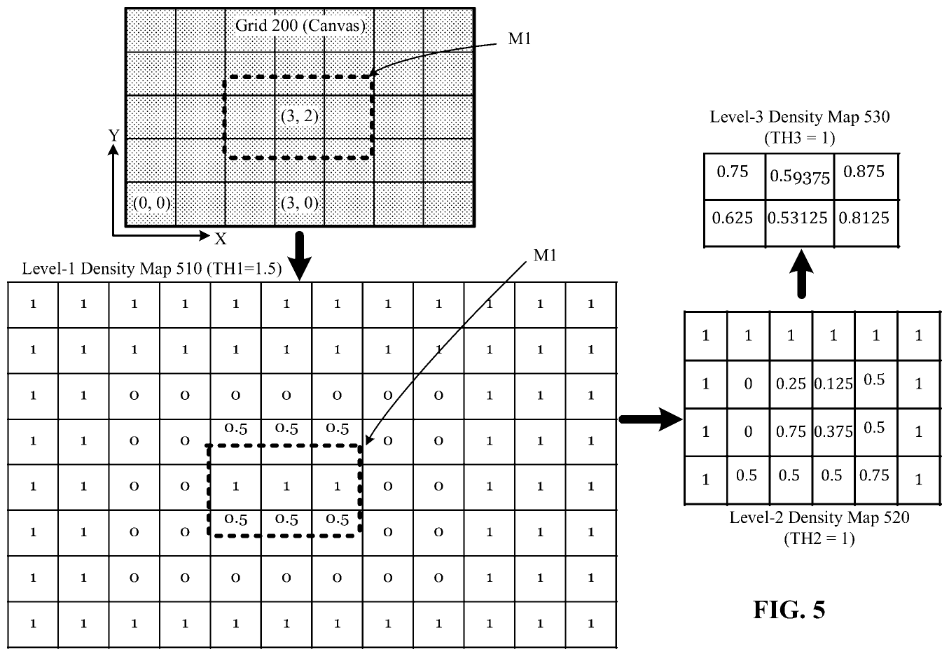

FIG. 5 illustrates an example of placing a macro M1 onto a canvas according to one embodiment. The canvas is represented by grid 200, with the (X, Y) coordinate (0, 0) at the lower left corner. Macro M1 (shown as a dotted-line block) is to be placed at coordinate (3, 2); that is, the center of M1 is to be placed at (3, 2). To determine whether the placement is allowed, the density maps at levels one, two, and three are generated. If any density value in a level-n density map exceeds a level-n density threshold, the placement is disallowed. The placement is allowed if all density values in each level of the density map do not exceed the corresponding density threshold.

As mentioned in connection with FIG. 2, grid 200 is padded with rows and columns such that the overall grid width and height are divisible by 2^{(L-1)}, where L=3 in this example. To form a level-1 density map 510, each cell of grid 200 is assigned density=0, and each padded cell is assigned density=1. When macro M1 is placed at (3, 2), level-1 density map 510 is updated for the grid cells occupied by M1. More specifically, the density value of each of the nine grid cells occupied by M1 is incremented by the grid area size occupied by M1. The updated level-1 density map 510 includes 6 cells with density=0.5, indicating that M1 occupies a half-cell area in each of those 6 cells, and 3 cells with density=1, indicating that M1 occupies an entire cell area in each of those 3 cells. Suppose that the level-1 density threshold (TH1)32 1.5. Since none of the density values in level-1 density map 510 exceed 1.5, the process proceeds to level-2 density calculations.

A level-2 density map 520 is generated from level-1 density map 510. Level-1 density map 510 can be partitioned into non-overlapping groups of (2×2) cells. The density values of each group are averaged to produce a density value in level-2 density map 520. Suppose that the level-2 density threshold (TH2)=1. Since none of the density values in level-2 density map 520 exceed 1, the process proceeds to level-3 density calculations.

Similarly, a level-3 density map 530 is generated from level-2 density map 520. Level-2 density map 520 can be partitioned into non-overlapping groups of (2×2) cells. The density values of each group are averaged to produce a density value in level-3 density map 530. Suppose that the level-3 density threshold (TH3)=1. Since none of the density values in level-3 density map 530 exceed 1 and the process has reached the highest level in this example, the process terminates and macro M1 is allowed to be placed at coordinate (3, 2) on the canvas.

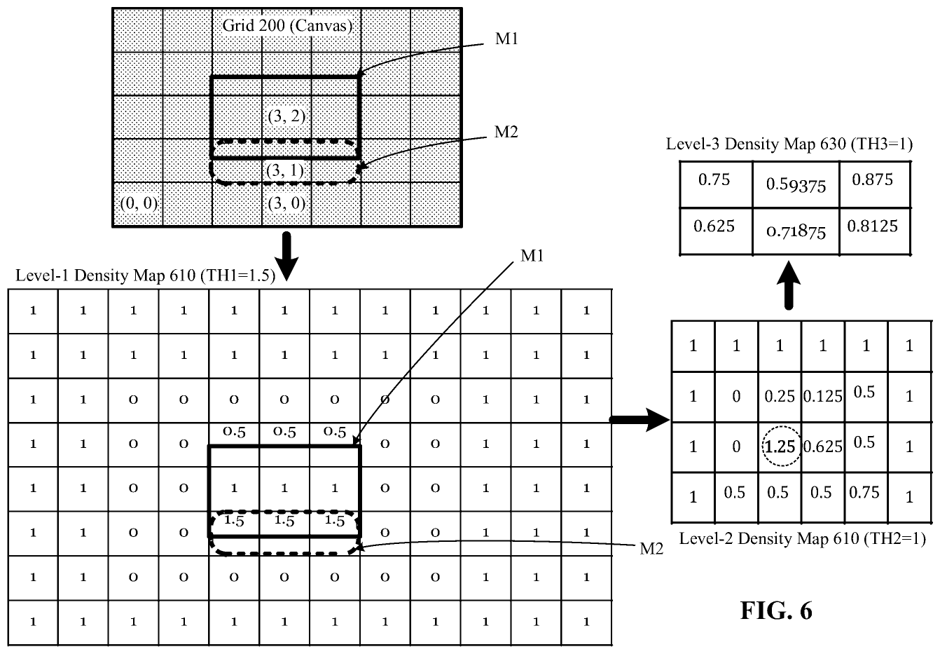

FIG. 6 illustrates an example of placing a second macro M2 onto the canvas represented by grid 200 according to one embodiment. Macro M1 (shown as a solid-line block) has been placed at coordinate (3, 2). Macro M2 (shown as a dotted-line block) is to be placed at coordinate (3, 1). To determine whether the placement of M2 is allowed, density maps 510, 520, and 530 (FIG. 5) are updated.

With respect to M2's level-1 density map 610, each of the three cells occupied by M2 has its density value incremented by 1 to become 1.5, which does not exceed the threshold TH1=1.5. M2's level-2 density map 620 is also updated; one of the density values (shown in a dotted-line circle) has a density value of 1.25, which exceeds the threshold TH2=1. Thus, the placement of M2 at (3, 1) is disallowed.

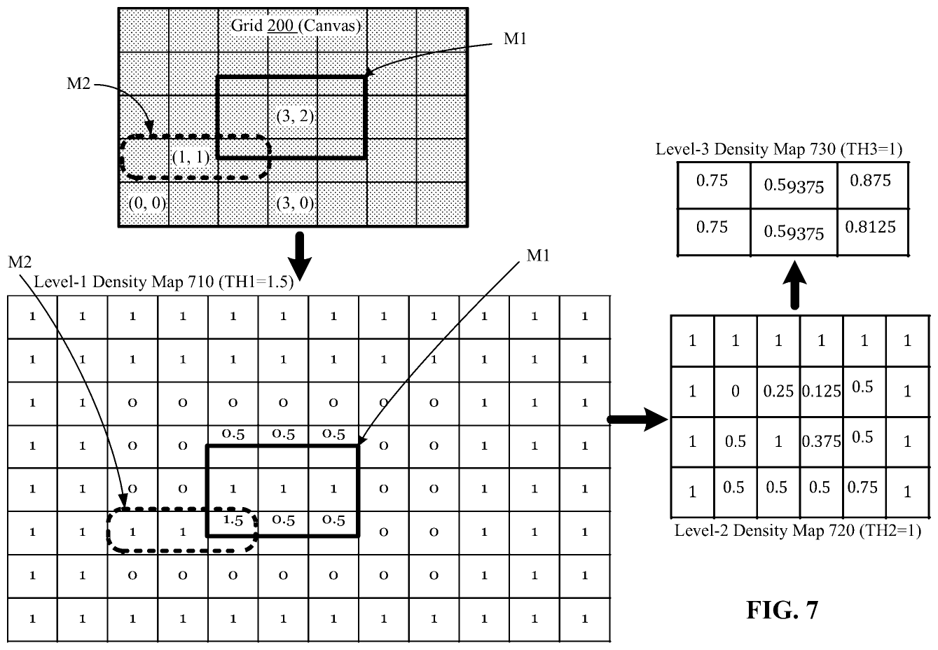

FIG. 7 illustrates another example of placing macro M2 onto the canvas represented by grid 200 according to one embodiment. In this example, macro M2 (shown as a dotted-line block) is to be placed at coordinate (1, 1). To determine whether the placement is allowed, the density maps 510, 520, and 530 (FIG. 5) are updated.

With respect to M2's level-1 density map 710, each of the three cells occupied by M2 has its density value incremented by 1 to become 1, 1, and 1.5, none of which exceeds the threshold TH1=1.5. M2's level-2 density map 720 is also updated; none of the density values exceeds the threshold TH2=1. M2's level-3 density map 730 is also updated; none of the density values exceeds the threshold TH3=1. Thus, the placement of M2 at (1, 1) is allowed.

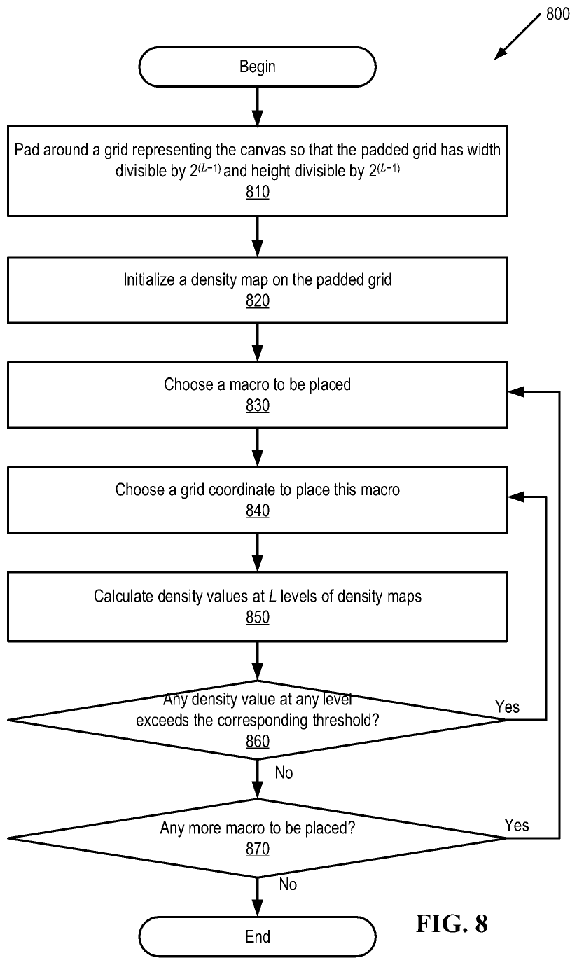

FIG. 8 is a flow diagram illustrating a method 800 for macro placement according to a first embodiment. Method 800 may be performed by a macro placement tool, which may be implemented by software running on a computing system. Method 800 begins at step 810 with the placement tool padding around a grid (e.g., grid 200 in FIG. 2) representing a canvas so that the padded grid has width divisible by 2^{(L-1)} and height divisible by 2^{(L-1)}. At step 820, the placement tool initializes a density map on the padded grid. The placement tool at step 830 chooses a macro to be placed, and at step 840 chooses a grid coordinate to place the macro. At step 850, the placement tool calculates density values at L levels of density maps. If, at step 860, the placement tool determines that a density value at a density map level exceeds the corresponding threshold, steps 840-860 are repeated until all density values of all levels of density maps are less than or equal to the corresponding threshold. When all density values of all levels of density maps are less than or equal to the corresponding threshold, the chosen macro is placed on the chosen coordinate. Method 800 proceeds to step 870 to determine whether there are more macros to be placed. Steps 830-870 are repeated until all macros are placed on the canvas.

In the following description, a placement tool generates density maps using 1-D average- pooling filters placed over a canvas. The 1-D average-pooling filters include horizontal average- pooling filters and vertical average-pooling filters.

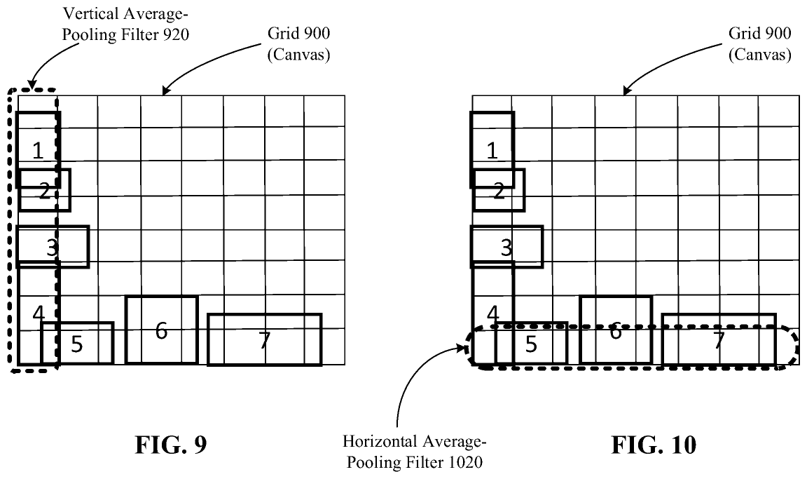

FIG. 9 illustrates an example of a vertical average-pooling filter 920 placed over a grid 900 representing a canvas according to one embodiment. Vertical average-pooling filter 920 covers a vertical slice of grid 900; an example of a vertical slice is an entire column. FIG. 10 illustrates an example of a horizontal average-pooling filter 1020 placed over grid 900 according to one embodiment. Horizontal average-pooling filter 1020 covers a horizontal slice of grid 900; an example of a horizontal slice is an entire row. In the examples of FIG. 9 and FIG. 10, seven macros are placed on the canvas. The placement tool allows some amount of overlap between the macros, where the allowable amount is defined by a density threshold. A refiner can be used after the placement of the macros to eliminate the overlaps between the macros.

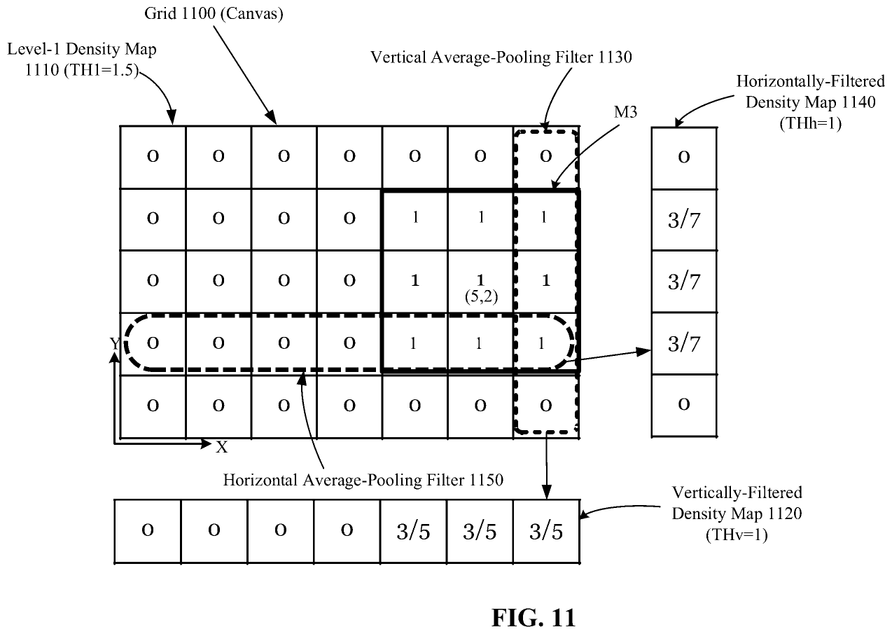

FIG. 11 illustrates an example of placing a macro M3 on a grid 1100 representing a canvas according to one embodiment. First, a level-1 density map 1110 is generated on grid 1100 with M3 placed at the grid coordinate (5, 2). If any of the level-1 density values exceeds the level-1 density threshold (e.g., TH1=1.5), the placement is disallowed. Subsequently, a vertically-filtered density map 1120 is generated using a vertical average-pooling filter 1130. Each density value of map 1120 is generated by averaging the level-1 density values in the grid cells covered by vertical average-pooling filter 1130. In this example, W density values corresponding to the W columns are generated. If any of the density values in map 1120 exceeds the corresponding density threshold (e.g., THIv=1), the placement is disallowed. A horizontally-filtered density map 1140 is generated using a horizontal average-pooling filter 1150. Each density value of map 1140 is generated by averaging the level-1 density values in the grid cells covered by horizontal average-pooling filter 1150. In this example, H density values corresponding to the HI rows are generated. If any of the density values in map 1140 exceeds the corresponding density threshold (e.g., THh=1), the placement is disallowed.

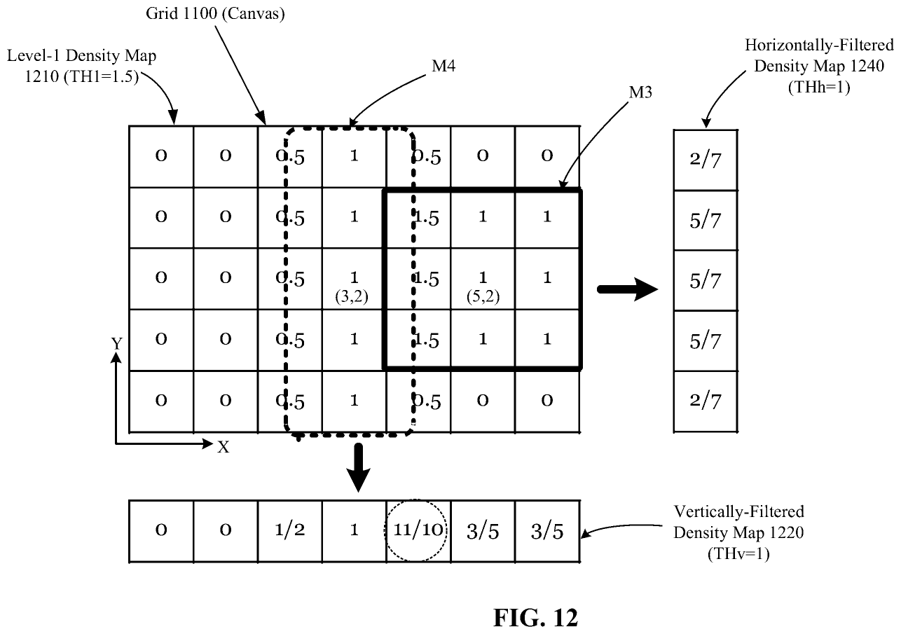

FIG. 12 illustrates an example of placing a second macro M4 on grid 1100 according to one embodiment. After the placement of M3 at (5, 2), macro M4 (shown as a dotted-line block) is to be placed at grid coordinate (3, 2). First, a level-1 density map 1210 is generated with M3 and M4 placed at (5, 2) and (3, 2), respectively. If any of the level-1 density values exceeds the level-1 density threshold (e.g., TH1=1.5), the placement is disallowed. Subsequently, vertically-filtered density map 1220 is generated using vertical average-pooling filter 1130 (FIG. 11). Each density value of map 1220 is generated by averaging the level-1 density values in the grid cells covered by vertical average-pooling filter 1130. If any of the density values in map 1220 exceeds the corresponding density threshold (e.g., THv=1), the placement is disallowed. In this example, one of the density values in map 1220 is 11/10, which exceeds THv=1. Thus, the placement of M4 at (3, 2) is disallowed, regardless of the density values in a horizontally-filtered density map 1240.

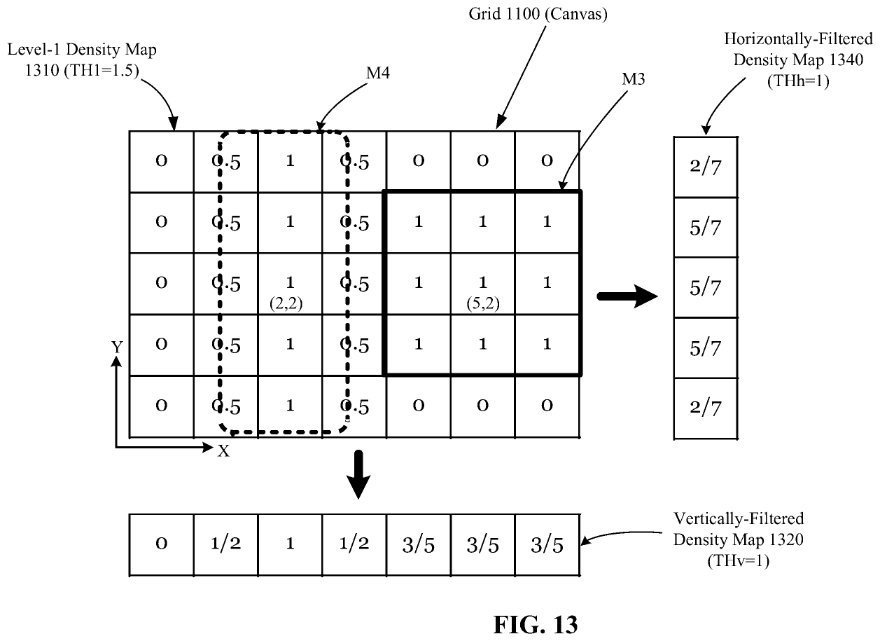

FIG. 13 illustrates another example of placing macro M4 on grid 1100 according to one embodiment. After the placement of M3 at (5, 2), macro M4 (shown as a dotted-line block) is to be placed at grid coordinate (2, 2). First, a level-1 density map 1310 is generated with M3 and M4 placed at (5, 2) and (2, 2), respectively. If any of the level-1 density values exceeds the level-1 density threshold (e.g., TH1=1.5), the placement is disallowed. Subsequently, vertically-filtered density map 1320 is generated using vertical average-pooling filter 1130 (FIG. 11). Each density value of map 1320 is generated by averaging the level-1 density values in the grid cells covered by vertical average-pooling filter 1130. A horizontally-filtered density map 1340 is generated using horizontal average-pooling filter 1150 (FIG. 11). Each density value of map 1340 is generated by averaging the level-1 density values in the grid cells covered by horizontal average-pooling filter 1150. In this example, none of the density values in maps 1320 and 1340 exceed the respective thresholds. Thus, the placement of M4 at (2, 2) is allowed.

In the examples of FIG. 11, FIG. 12, and FIG. 13, the vertically-filtered density maps (1120, 1220, and 1320) and the horizontally-filtered density map (1140, 1240, and 1340) are also referred to as level-2 density maps of different orientations.

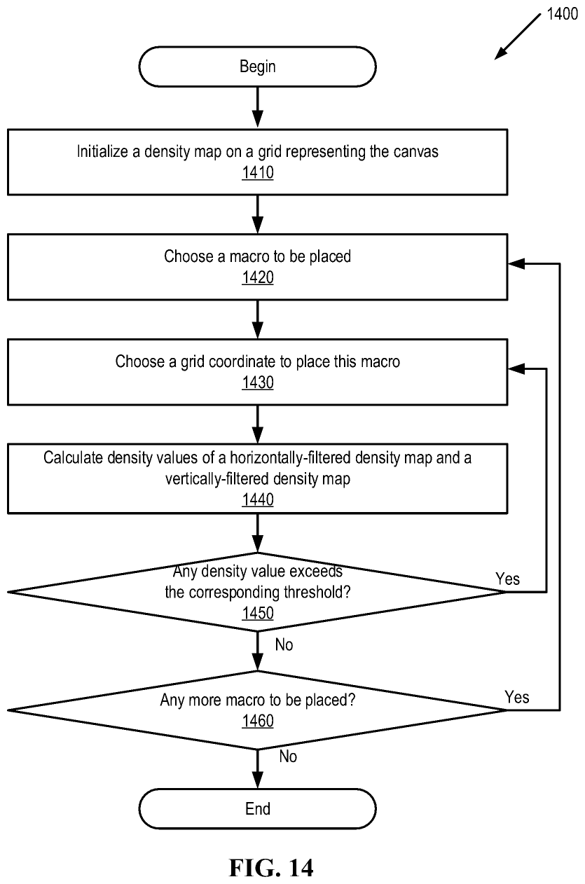

FIG. 14 is a flow diagram illustrating a method 1400 for macro placement according to a second embodiment. Method 1400 may be performed by a macro placement tool, which may be implemented by software running on a computing system. Method 1400 begins at step 1410 with the placement tool initializing a density map on a grid representing a canvas; e.g., by assigning zeros to grid cells. The placement tool at step 1420 chooses a macro to be placed, and at step 1430 chooses a grid coordinate to place the macro. At step 1440, the placement tool calculates the density values of a horizontally-filtered density map and a vertically-filtered density map. If, at step 1450, the placement tool determines that a density value of a density map exceeds the corresponding threshold, steps 1430-1450 are repeated until all density values of all density maps are less than or equal to the corresponding threshold. When all density values of all density maps are less than or equal to the corresponding threshold, the chosen macro is placed on the chosen coordinate. Method 1400 proceeds to step 1460 to determine whether there are more macros to be placed. Steps 1420-1460 are repeated until all macros are placed on the canvas.

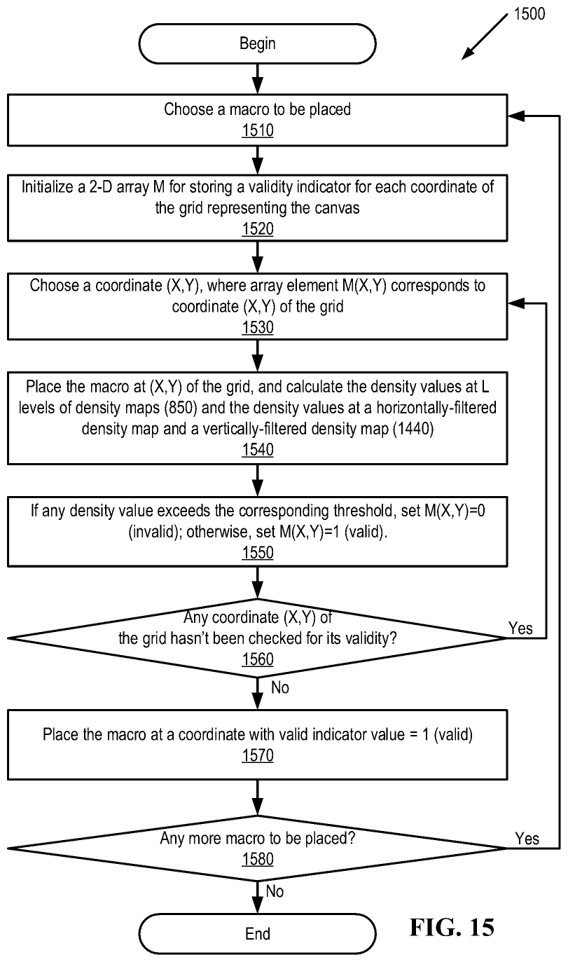

FIG. 15 is a flow diagram illustrating a method 1500 for macro placement according to an alternative embodiment that combines the first and second embodiments. Method 1500 may be performed by a macro placement tool, which may be implemented by software running on a computing system. In this method, the action masks is a 2-D array M which stores a validity indicator for each coordinate of a grid that represents a canvas. Method 1500 begins at step 1510 with the placement tool choosing a macro to be placed on the canvas. At step 1520, the 2-D array M is initialized. At step 1530, a coordinate (X,Y) is chosen, where array element M (X,Y) corresponds to coordinate (X,Y) of the grid. At step 1540, the placement tool places the macro at (X,Y) of the grid, and calculates the density values at L levels of density maps (e.g., multi- resolution density maps calculated at step 850 of FIG. 8) and the density values at a horizontally- filtered density map and a vertically-filtered density map (e.g., 1-D density maps calculated at step 1440 of FIG. 14). If any density value exceeds the corresponding threshold, the placement tool at step 1550 sets M (X,Y)=0 (i.e., invalid); otherwise, the placement tool sets M (X,Y)=1 (i.e., valid). If, at step 1560, it is determined that there is an coordinate (X,Y) of the grid that has not been checked for its validity, steps 1530-1560 are repeated until all coordinates of the grid are checked for their validity. After the validity indicators of all elements of M are set and stored in M, at step 1570, the placement tool selects a coordinate with validity indicator value=1 (valid) to place the macro. Method 1500 proceeds to step 1580 to determine whether there are more macros to be placed. Steps 1510-1580 are repeated until all macros are placed on the canvas.

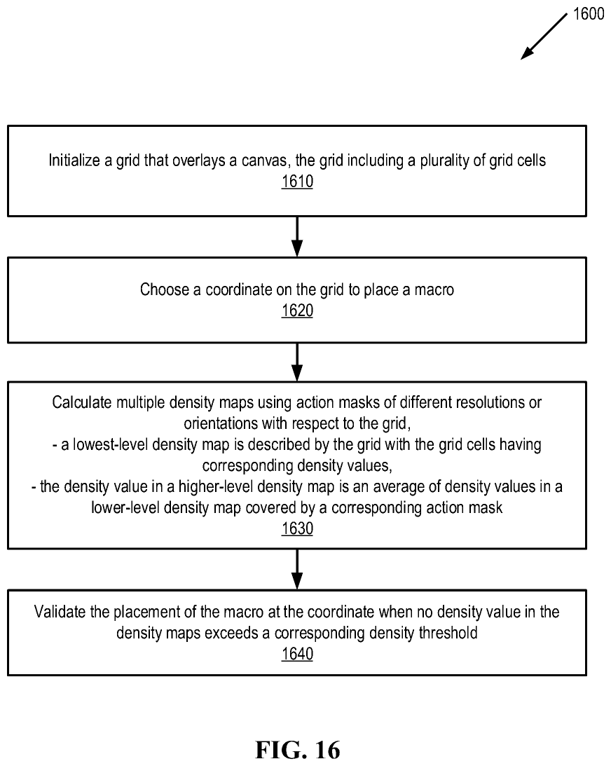

FIG. 16 is a flow diagram illustrating a method 1600 for macro placement according to one embodiment. Method 1600 may be performed by a macro placement tool, which may be implemented by software running on a computing system. Method 1600 begins at step 1610 with the placement tool initializing a grid that overlays a canvas. The grid includes columns and rows of grid cells. The grid may be a grid representing the canvas, or a padded grid that pads column(s) and/or row(s) around a grid representing the canvas. The placement tool at step 1620 chooses a coordinate on the grid to place the macro. At step 1630, the placement tool calculates multiple density maps using average-pooling filters of different resolutions or orientations with respect to the grid. The lowest-level (i.e., level-1) density map is described by the grid with the grid cells having corresponding density values. Furthermore, the density value in a higher-level density map is an average of density values in a lower-level density map covered by a corresponding average-pooling filter. At step 1640, the placement tool validates the placement of the macro at the coordinate when no density value in the density maps exceeds a corresponding density threshold.

In one embodiment, after the macro is placed on the coordinate of the grid, the density value of each grid cell in a level-1 density map is incremented by a grid area size occupied by the macro.

In one embodiment, each density value in a level-n density map is an average of the density values in a level-(n−1) density map covered by a two-dimensional (2-D) average-pooling filter, where n is an integer greater than one. The level-n density map is smaller in size than the level-(n−1) density map. In one embodiment, the 2-D average-pooling filter used to generate the level-n density map is of size 2⁽ⁿ⁻¹⁾×2⁽ⁿ⁻¹⁾, with each grid cell size equal to one. In another embodiment, the 2-D average-pooling filter applied to each level of the density map is of size 2×2, with each grid cell size equal to one.

In one embodiment, the grid includes padded cells at an outer perimeter of the grid cells representing the canvas, and the grid is padded to have a number of columns divisible by 2⁽ⁿ⁻¹⁾ and a number of rows divisible by 2⁽ⁿ⁻¹⁾), n being a number of levels of the density maps. When initializing the lowest-level density map (i.e., the level-1 density map), each padded cell is assigned a density value of 1 and each grid cell representing the canvas is assigned a density value of 0.

In one embodiment, the density maps are calculated using one-dimensional average-pooling filters of different orientations. The one-dimensional average-pooling filters include a vertical average-pooling filter and a horizontal average-pooling filter. The vertical average-pooling filter is applied on each column of the grid, which is to average the density values in each column to produce a density value in a vertically-filtered density map. The horizontal average-pooling filter is also applied on each row of the grid, which is to average the density values in each row to produce a density value in a horizontally-filtered density map.

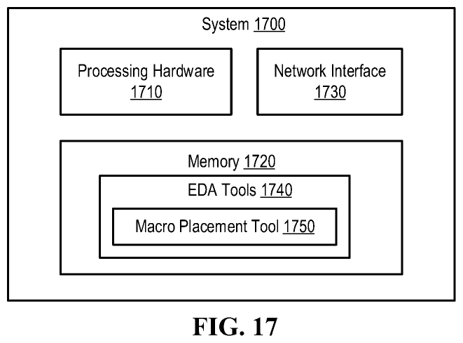

FIG. 17 illustrates an example of a system 1700 according to one embodiment. System 1700 includes processing hardware 1710, a memory 1720, and a network interface 1730. In one embodiment, processing hardware 1710 may include one or more processors and accelerators, such as one or more of: a central processing unit (CPU), a GPU, a digital processing unit (DSP), an AI processor, a tensor processor, a neural processor, a multimedia processor, other general-purpose and/or special-purpose processing circuitry.

System 1700 further includes the memory 1720 coupled to processing hardware 1710. Memory 1720 may include memory devices such as dynamic random access memory (DRAM), SRAM, flash memory, and other non-transitory machine-readable storage media; e.g., volatile or non-volatile memory devices. Memory 1720 may further include storage devices, for example, any type of solid-state or magnetic storage device. In one embodiment, memory 1720 may store one or more EDA tools 1740 including but not limited to neural networks, AI agents, and other tools for macro placement. A non-limiting example of EDA tools 1740 is a macro placement tool 1750 operative to perform method 800 (FIG. 8), method 1400 (FIG. 14), method 1500 (FIG. 15), and method 1600 (FIG. 16). In some embodiments, memory 1720 may store instructions which, when executed by processing hardware 1710, cause the processing hardware to perform the aforementioned methods and operations for macro placements.

In some embodiments, system 1700 may also include a network interface 1730 to connect to a wired and/or wireless network. It is understood that the embodiment of FIG. 17 is simplified for illustration purposes. Additional hardware components may be included.

Various functional components or blocks have been described herein. As will be appreciated by persons skilled in the art, the functional blocks will preferably be implemented through circuits (either dedicated circuits or general-purpose circuits, which operate under the control of one or more processors and coded instructions), which will typically comprise transistors that are configured in such a way as to control the operation of the circuity in accordance with the functions and operations described herein.

While the invention has been described in terms of several embodiments, those skilled in the art will recognize that the invention is not limited to the embodiments described, and can be practiced with modification and alteration within the spirit and scope of the appended claims. The description is thus to be regarded as illustrative instead of limiting.

What is claimed is:

1. A method for macro placement on a canvas, comprising:
initializing a grid that represents the canvas, the grid including a plurality of grid cells;
choosing a coordinate on the grid to place a macro;
calculating a plurality of density maps using average-pooling filters of multiple resolutions or orientations, wherein a lowest-level density map is described by the grid with each grid cell having a corresponding density value, and wherein a density value in a higher-level density map is calculated by performing an average-pooling operation on density values in a lower-level density map; and
validating placement of the macro at the coordinate when no density value in the density maps exceeds a corresponding density threshold.

2. The method of claim 1, further comprising: calculating a density value in a level-n density map by applying a two-dimensional (2-D) average-pooling filter on a level-(n−1) density map, n being an integer greater than one, and the level-n density map is smaller in size than the level-(n−1) density map.

3. The method of claim 2, wherein the 2-D average-pooling filter used to generate the level-n density map is of size 2⁽ⁿ⁻¹⁾×2⁽ⁿ⁻¹⁾, and operates to average 2⁽ⁿ⁻¹⁾×2⁽ⁿ⁻¹⁾ density values in the level-1 density map.

4. The method of claim 2, wherein the 2-D average-pooling filter applied to each of a plurality of levels of density maps is of size 2×2, and operates to average 2×2 density values in the level-(n−1) density map.

5. The method of claim 1, wherein the grid includes padded cells at an outer perimeter of the grid cells representing the canvas, and the grid is padded to have a number of columns divisible by 2⁽ⁿ⁻¹⁾ and a number of rows divisible by 2⁽ⁿ⁻¹⁾, n being a number of levels of the density maps.

6. The method of claim 5, further comprising:
initializing the lowest-level density map, which is a level-1 density map, by assigning a density value of 1 to each padded cell and assigning a density value of 0 to each grid cell representing the canvas.

7. The method of claim 1, further comprising:
calculating the density maps using one-dimensional (1-D) average-pooling filters of multiple orientations, wherein the 1-D average-pooling filters include a vertical average-pooling filter and a horizontal average-pooling filter.

8. The method of claim 7, further comprising:
applying the vertical average-pooling filter on each of a plurality of columns of the grid, wherein applying the vertical average-pooling filter is to average the density values in each column to produce a density value in a vertically-filtered density map.

9. The method of claim 7, further comprising:
applying the horizontal average-pooling filter on each of a plurality of rows of the grid, wherein applying the horizontal average-pooling filter is to average the density values in each row to produce a density value in a horizontally-filtered density map.

10. The method of claim 1, wherein calculating the plurality of density maps further comprises:
calculating a first set of density maps using 2-D average-pooling filters of multiple resolutions with respect to the grid;
calculating a second set of density maps using 1-D average-pooling filters of a horizontal orientation and a vertical orientation; and
validating the placement of the macro at the coordinate when all density values in the first set and the second set of density maps are within corresponding density thresholds.

11. A system operative to perform macro placement on a canvas, comprising:
processing hardware; and
memory coupled to the processing hardware, wherein the processing hardware is operative to:
initialize a grid that represents the canvas, the grid including a plurality of grid cells;
choose a coordinate on the grid to place a macro;
calculate a plurality of density maps using average-pooling filters of multiple resolutions or orientations, wherein a lowest-level density map is described by the grid with each grid cell having a corresponding density value, and wherein a density value in a higher-level density map is calculated by performing an average-pooling operation on density values in a lower-level density map; and
validate placement of the macro at the coordinate when no density value in the density maps exceeds a corresponding density threshold.

12. The system of claim 11, wherein the processing hardware is further operative to:
calculate a density value in a level-n density map by applying a two-dimensional (2-D) average-pooling filter on a level-(n−1) density map, n being an integer greater than one, and the level-n density map is smaller in size than the level-(n−1) density map.

13. The system of claim 12, wherein the 2-D average-pooling filter used to generate the level-n density map is of size 2⁽ⁿ⁻¹⁾×2⁽ⁿ⁻¹⁾, and operates to average 2⁽ⁿ⁻¹⁾×2⁽ⁿ⁻¹⁾ density values in the level-1 density map.

14. The system of claim 12, wherein the 2-D average-pooling filter applied to each of a plurality of levels of density maps is of size 2×2, and operates to average 2×2 density values in the level-(n−1) density map.

15. The system of claim 11, wherein the grid includes padded cells at an outer perimeter of the grid cells representing the canvas, and the grid is padded to have a number of columns divisible by 2⁽ⁿ⁻¹⁾ and a number of rows divisible by 2⁽ⁿ⁻¹⁾, n being a number of levels of the density maps.

16. The system of claim 15, wherein the processing hardware is further operative to:
initialize the lowest-level density map, which is a level-1 density map, by assigning a density value of 1 to each padded cell and assigning a density value of 0 to each grid cell representing the canvas.

17. The system of claim 11, wherein the processing hardware is further operative to:
calculate the density maps using one-dimensional (1-D) average-pooling filters of multiple orientations, wherein the 1-D average-pooling filters include a vertical average-pooling filter and a horizontal average-pooling filter.

18. The system of claim 17, wherein the processing hardware is further operative to:
apply the vertical average-pooling filter on each of a plurality of columns of the grid, wherein applying the vertical average-pooling filter is to average the density values in each column to produce a density value in a vertically-filtered density map.

19. The system of claim 17, wherein the processing hardware is further operative to:
apply the horizontal average-pooling filter on each of a plurality of rows of the grid, wherein applying the horizontal average-pooling filter is to average the density values in each row to produce a density value in a horizontally-filtered density map.

20. The system of claim 11, wherein the processing hardware, when calculating the plurality of density maps, is further operative to:
calculate a first set of density maps using 2-D average-pooling filters of multiple resolutions with respect to the grid;
calculate a second set of density maps using 1-D average-pooling filters of a horizontal orientation and a vertical orientation; and
validate the placement of the macro at the coordinate when all density values in the first set and the second set of density maps are within corresponding density thresholds.
